(19) United States
(12) Patent Application Publication
(10) Pub. No.: US 2026/0186418 A1
(43) Pub. Date: Jul. 2, 2026

(54) SUBSTRATE PROCESSING DEVICE

(71) Applicant: SEMES CO., LTD., Cheonan-si (KR)

(72) Inventors: Ju Yeon CHO, Suwon-si (KR); Dae Sung KIM, Cheonan-si (KR); Kyu Hwan CHANG, Hwaseong-si (KR); Ki Moon KANG, Yongin-si (KR); Byeong Geun KIM, Seoul (KR)

(21) Appl. No.: 19/393,750

(22) Filed: Nov. 19, 2025

(30) Foreign Application Priority Data
Dec. 31, 2024 (KR) 10-2024-0202384

(51) Int. Cl. G03F 7/16; B05B 1/00

(52) U.S. Cl. CPC G03F 7/168; B05B 1/00; G03F 7/162

(57) ABSTRACT

A substrate processing device includes an application module applying a processing liquid to a substrate and performing heat treatment and a buffer module loading a substrate into the application module or removing a substrate from the application module, wherein the application module includes an application chamber portion applying photoresist (PR) to the substrate, a heat treatment chamber portion heat-treating the substrate, and a PR bottle cabinet storing the PR.

### CROSS-REFERENCE TO RELATED APPLICATION(S)

This application claims benefit of priority to Korean Patent Application No. 10-2024-0202384 filed on Dec. 31, 2024 in the Korean Intellectual Property Office, the disclosure of which is incorporated herein by reference in its entirety.

### BACKGROUND

### 1. FIELD

The present disclosure relates to a substrate processing device.

### 2. DESCRIPTION OF RELATED ART

Generally, a semiconductor substrate manufacturing process may be divided into a thin film process of depositing a thin film on a glass substrate, a photolithography process of forming the thin film into a desired pattern, and an etching process of etching the thin film according to the pattern. By repeatedly performing these processes, a semiconductor substrate may be manufactured.

Meanwhile, as substrate manufacturing methods have been diversified, application-dedicated equipment (or coating-only equipment) that does not perform an exposure process has been developed. Since application-dedicated equipment does not utilize an exposure device, structures, such as a development chamber, an interface module, or the like are not required. Therefore, it may be difficult to apply the related art equipment layout structure as it is to application-dedicated equipment, and a new dedicated layout structure is required.

### SUMMARY

An aspect of the present disclosure is to provide a substrate processing device having a layout structure that may efficiently use application-dedicated equipment (or coating-only equipment).

The problems to be solved by the present disclosure are not limited thereto, and those skilled in the art will understand that other technical problems, not mentioned above, may be derived from the components used in the following specifications and drawings.

According to an aspect of the present disclosure, a substrate processing device includes: an application module applying a processing liquid to a substrate and performing heat treatment; and a buffer module loading a substrate into the application module or removing a substrate from the application module, wherein the application module includes: an application chamber portion applying photoresist (PR) to the substrate; a heat treatment chamber portion heat-treating the substrate; and a PR bottle cabinet storing the PR.

According to another aspect of the present disclosure, a substrate processing device includes: an application module applying a processing liquid to a substrate and performing heat treatment; and a buffer module loading a substrate into the application module or removing a substrate from the application module, wherein the application module includes: an application chamber portion applying photoresist (PR) to the substrate; a heat treatment chamber portion heat-treating the substrate; and a PR bottle cabinet storing the PR, wherein the application chamber portion includes: a support portion supporting and rotating the substrate; a nozzle portion applying the PR to the substrate; and a processing vessel recovering the PR applied to the substrate.

According to another aspect of the present disclosure, a substrate processing device includes: an application module applying a processing liquid to a substrate and performing heat treatment; and a buffer module loading a substrate into the application module or removing the substrate from the application module, wherein the application module includes: an application chamber portion applying photoresist (PR) onto the substrate; a heat treatment chamber portion heat-treating the substrate; a PR bottle cabinet storing the PR; a PR pump unit supplying the PR from the PR bottle cabinet to the application chamber portion; and a PR pipe connecting the PR pump unit and the application chamber portion to supply the PR, and wherein the application module includes a plurality of layers including a lower layer, a middle layer, and an upper layer, and the heat treatment chamber portion includes a preprocessing chamber, a lower film heat treatment chamber, and a surface film heat treatment chamber, the application chamber portion includes a lower film application chamber and a surface film application chamber, the PR bottle cabinet and the preprocessing chamber are provided in the lower layer of the application module, the PR pump unit, the lower film application chamber, and the lower film heat treatment chamber are provided in the middle layer of the application module, the PR pump unit, the surface film application chamber, and the surface film heat treatment chamber are provided in the upper layer of the application module, and the PR pipe connected to each layer is configured to have the same length.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a top view of the related art substrate processing device;

FIG. 2 is a view of the related art substrate processing device of FIG. 1 taken in the A-A direction;

FIG. 3 is a view of the related art substrate processing device of FIG. 1 taken in the B-B direction;

FIG. 4 is a perspective view including the front of a substrate processing device according to an embodiment of the present disclosure;

FIG. 5 is a perspective view including the rear of a substrate processing device according to an embodiment of the present disclosure;

FIG. 6 is a front view of a substrate processing device according to an embodiment of the present disclosure;

FIG. 7 is a rear view of a substrate processing device according to an embodiment of the present disclosure;

FIG. 8 is a top view of a substrate processing device according to an embodiment of the present disclosure; and

FIG. 9 illustrates a cross-sectional view of the substrate processing device of FIG. 8, taken in the C-C direction.

### DETAILED DESCRIPTION

Hereinafter, embodiments will be described in detail with reference to the accompanying drawings such that they may be easily practiced by those skilled in the art to which the present disclosure pertains. In describing the present disclosure, if a detailed explanation for a related known function or construction is considered to unnecessarily divert the gist of the present disclosure, such explanation will be omitted but would be understood by those skilled in the art. Also, similar reference numerals are used for the similar parts throughout the specification. In this disclosure, terms., such as “above,” “upper portion,” “upper surface,” “below,” “lower portion,” “lower surface,” “lateral surface,” and the like, are determined based on the drawings, and in actuality, the terms may be changed according to a direction in which a device or an element is disposed.

It will be understood that when an element is referred to as being “connected to” another element, it may be directly connected to the other element or intervening elements may also be present. In contrast, when an element is referred to as being “directly connected to” another element, no intervening elements are present. In addition, unless explicitly described to the contrary, the word “comprise” and variations, such as “comprises” or “comprising,” will be understood to imply the inclusion of stated elements but not the exclusion of any other elements.

The present disclosure may be implemented in various different forms and is not limited to the embodiments described herein.

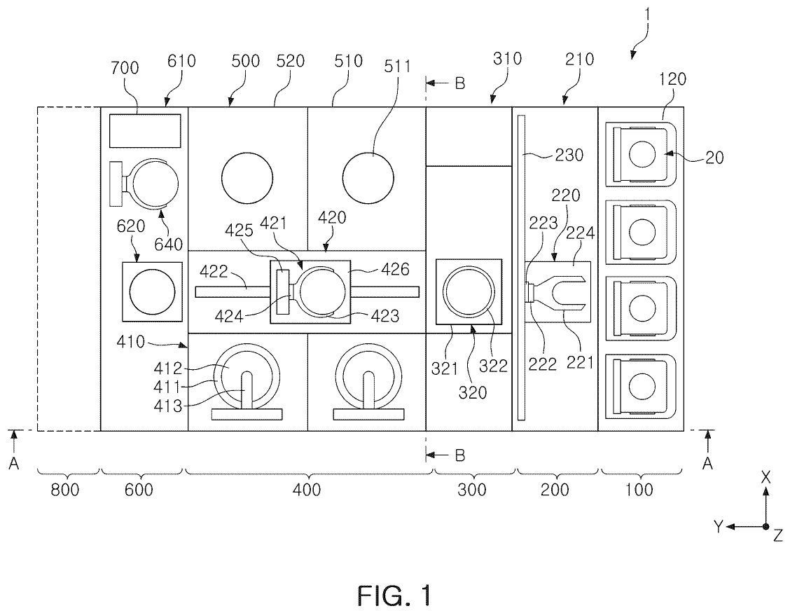

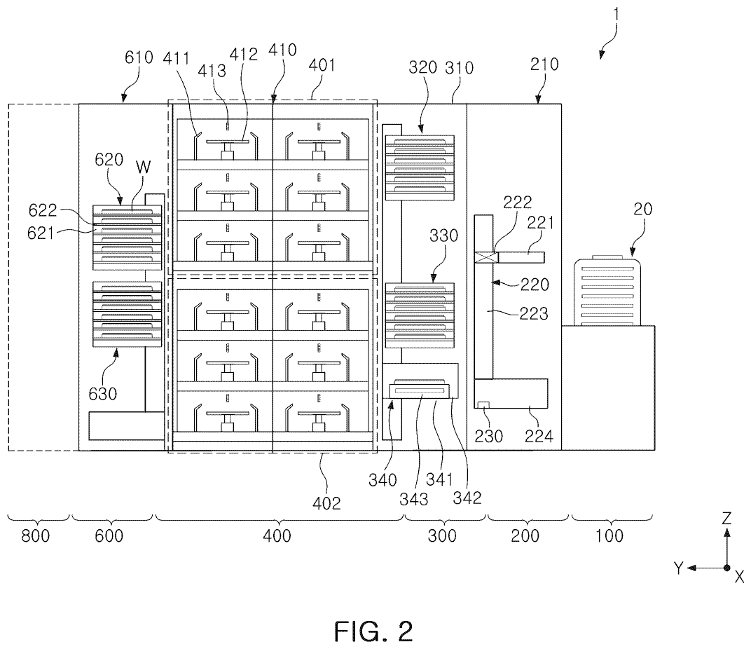

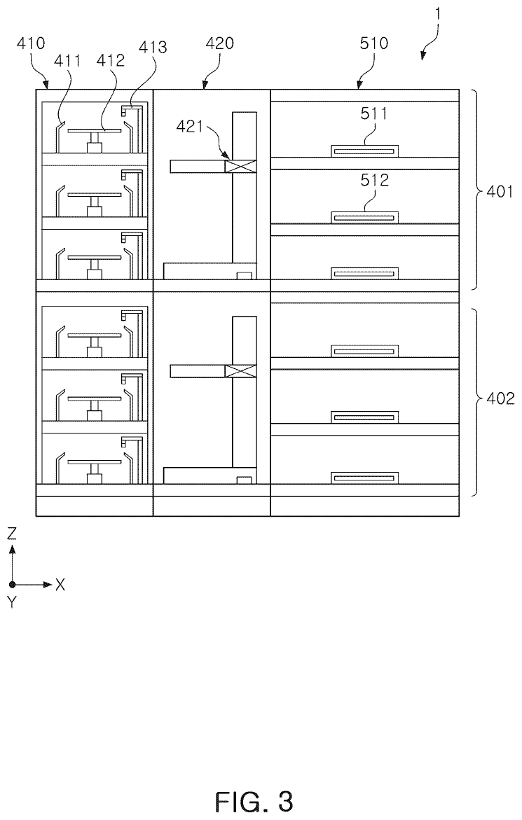

FIG. 1 is a top view of the related art substrate processing device, FIG. 2 is a view of the related art substrate processing device of FIG. 1, taken in the A-A direction, and FIG. 3 is a view of the related art substrate processing device of FIG. 1, taken in the B-B direction.

Referring to FIGS. 1 to 3, the related art substrate processing device 1 includes a load port 100, an index module 200, a buffer module 300, an application and development module 400, an interface module 600, and a purge module 700. The load port 100, the index module 200, the buffer module 300, the application and development module 400, and the interface module 600 are sequentially arranged in a row in one direction. The purge module 700 may be provided within the interface module 600. Alternatively, the purge module 700 may be provided at various locations, such as at a location in which an exposure device at the rear of the interface module 600 is connected or at the side of the interface module 600.

Hereinafter, a direction in which the load port 100, the index module 200, the buffer module 300, the application and development module 400, and the interface module 600 are arranged is referred to as a first direction Y, a direction, perpendicular to the first direction Y when viewed from above, is referred to as a second direction X, and a direction, perpendicular to the first direction Y and the second direction X, is referred to as a third direction Z.

A substrate W is moved while stored in a cassette 20. The cassette 20 has a structure that may be sealed from the outside. For example, a front open unified pod (FOUP) with a front door may be used as the cassette 20.

Hereinafter, the load port 100, the index module 200, the buffer module 300, the application and development module 400, the interface module 600, and the purge module 700 are described in detail.

The load port 100 has a mounting plate 120 on which the cassette 20 containing the substrate W is disposed. A plurality of mounting plates 120 are provided, and the mounting plates 120 are arranged in a row in the second direction X. While FIG. 2 illustrates an example with four mounting plates 120, the number may vary.

The index module 200 transfers the substrate W between the cassette 20 disposed on the mounting plate 120 of the load port 100 and the buffer module 300. The index module 200 includes a frame 210, an index robot 220, and a guide rail 230. The frame 210 is generally provided in the shape of a rectangular parallelepiped with a hollow interior and is disposed between the load port 100 and the buffer module 300. The frame 210 of the index module 200 may be provided at a lower height than the frame 310 of the buffer module 300. The index robot 220 and the guide rail 230 are disposed within the frame 210. The index robot 220 is provided such that a hand 221 for directly handling the substrate W may move and rotate in the first direction Y, the second direction X, and the third direction Z. The index robot 220 includes the hand 221, an arm 222, a support 223, and a pedestal 224. The hand 221 is fixedly installed on the arm 222. The arm 222 is provided as a retractable structure and rotatable structure. The support 223 is arranged such that a longitudinal direction thereof corresponds to the third direction Z. The arm 222 is coupled to the support 223 so as to be movable along the support 223. The support 223 is fixedly coupled to the pedestal 224. The guide rail 230 is provided such that a longitudinal direction thereof corresponds to the second direction X. The pedestal 224 is coupled to the guide rail 230 so as to be linearly movable along the guide rail 230. In addition, although not illustrated, a door opener for opening and closing a door of the cassette 20 is further provided on the frame 210.

The buffer module 300 includes a frame 310, a first buffer 320, a second buffer 330, and a cooling chamber 340. The frame 310 is provided in the shape of a rectangular parallelepiped with a hollow interior and is disposed between the index module 200 and the application and development module 400. The first buffer 320, the second buffer 330, and the cooling chamber 340 are disposed within the frame 310. The cooling chamber 340, the second buffer 330, and the first buffer 320 are sequentially disposed from below in the third direction Z. The first buffer 320 is disposed at a height corresponding to an application module 401 of the application and development module 400, and the second buffer 330 and the cooling chamber 340 are provided at a height corresponding to a development module 402 of the application and development module 400.

The first buffer 320 and the second buffer 330 each temporarily store a plurality of substrates W. The first buffer 320 includes a housing 321 and a plurality of supports 322. In the first buffer 320, the supports 322 are arranged within the housing 321 and are spaced apart from each other in the third direction Z. The second buffer 330 includes a housing 331 and a plurality of supports 332. In the second buffer 330, the supports 332 are arranged within the housing 331 and are spaced apart from each other in the third direction Z. One substrate W is disposed on each support 322 of the first buffer 320 and on each support 332 of the second buffer 330. The housing 331 has an opening in a direction in which the index robot 220 is provided so that the index robot 220 may load or unload the substrate W onto or from the support 332 within the housing 331. The first buffer 320 has a structure substantially similar to that of the second buffer 330. However, the housing 321 of the first buffer 320 has an opening in a direction in which the first buffer robot 360 is provided and in a direction in which an application robot 421 located in the application module 401 is provided. The number of supports 322 provided in the first buffer 320 and the number of supports 332 provided in the second buffer 330 may be the same or different. In an example, the number of supports 332 provided in the second buffer 330 may be greater than the number of supports 322 provided in the first buffer 320. The cooling chamber 340 cools each substrate W. The cooling chamber 340 includes a housing 341 and a cooling plate 342. The cooling plate 342 has an upper surface on which the substrate W is disposed and a cooling unit 343 cooling the substrate W. Various methods, such as cooling using coolant or cooling using a thermoelectric element, may be used as the cooling unit 343. In addition, the cooling chamber 340 may be provided with a lift pin assembly for positioning the substrate W on the cooling plate 342. The housing 341 has openings in a direction in which the index robot 220 is provided and in a direction in which a development robot is provided so that the index robot 220 and the development robot provided in the development module 402 may load or unload the substrate W onto or from the cooling plate 342. In addition, the cooling chamber 340 may be provided with doors for opening and closing the openings.

Although the embodiment in which the buffer module 300 includes the cooling chamber 340 has been described, the present disclosure is not limited thereto, and the cooling chamber 340 may be omitted as needed.

The application module 401 performs a process of applying a photosensitive solution, such as photoresist, to the substrate W and a heat treatment process, such as heating and cooling, on the substrate W before and after a resist application process. The application module 401 includes an application chamber 410, a heat treatment chamber unit 500, and a transfer chamber 420. The application chamber 410, the transfer chamber 420, and the heat treatment chamber unit 500 are sequentially arranged in the second direction X. That is, with respect to the transfer chamber 420, the application chamber 410 is provided on one side of the transfer chamber 420, and the heat treatment chamber unit 500 is provided on the other side of the transfer chamber 420,

A plurality of application chambers 410 are provided, each in the third direction Z. Furthermore, as illustrated in FIG. 1, a plurality of application chambers 410 may be provided in the first direction Y, or a single application chamber 410 may be provided in the first direction Y. The heat treatment chamber unit 500 includes a baking chamber 510 and a cooling chamber 520, and a plurality of baking chambers 510 and a plurality of cooling chambers 520 are provided in the third direction Z. The transfer chamber 420 is disposed parallel to the first buffer 320 of the buffer module 300 in the first direction 12. The application robot 421 and the guide rail 422 are located within the transfer chamber 420. The transfer chamber 420 has a generally rectangular shape. The application robot 421 transfers the substrate W between the baking chamber 510, the cooling chamber 520, the application chamber 410, and the first buffer 320 of the buffer module 300.

The guide rail 422 is arranged such that a longitudinal direction thereof is parallel to the first direction Y. The guide rail 422 guides the application robot 421 to move linearly in the first direction Y. The application robot 421 has a hand 423, an arm 424, a support 425, and a pedestal 426. The hand 423 is fixedly installed to the arm 424. The arm 424 is provided as a flexible structure to allow the hand 423 to move in a horizontal direction. The support 425 is provided such that a longitudinal direction thereof corresponds to the third direction Z. The arm 424 is coupled to the support 425 so that the arm 424 may move linearly in the third direction Z along the support 425. The support 425 is fixedly coupled to the pedestal 426, and the pedestal 426 is coupled to the guide rail 422 so as to be movable along the guide rail 422.

The application chambers 410 may all have the same structure, but the type of processing liquid used in each application chamber 410 may differ. The processing liquid may be a processing liquid for forming a photoresist film or an anti-reflection film.

The application chamber 410 applies the processing liquid onto the substrate W. The application chamber 410 may be provided with a processing unit including a cup portion 411, a support portion 412, and a nozzle portion 413.

For example, in the application chamber 410, one processing unit is disposed in the first direction Y. However, without being limited thereto, two or more processing units may be disposed in a single application chamber 410. Each processing unit may have the same structure. However, the type of processing liquid used in each processing unit may differ.

The cup portion 411 of the application chamber 410 has an open upper portion. The support portion 412 is disposed within the cup portion 411 and supports the substrate W. The support portion 412 is rotatably provided. The nozzle portion 413 supplies the processing liquid onto the substrate W disposed on the support portion 412. The processing liquid is applied to the substrate W using a spin coating method. In addition, the application chamber 410 may optionally be further provided with a nozzle (not shown)for supplying a cleaning solution, such as deionized water (DIW), to clean the surface of the substrate W to which the processing liquid has been applied and a back rinse nozzle (not shown)for cleaning a lower surface of the substrate W.

In the baking chamber 510, the substrate W may be heat-treated after being disposed by the application robot 421.

In the baking chamber 510, a prebaking process is performed to heat the substrate W to a predetermined temperature to remove organic substances or moisture from the surface of the substrate W before applying the processing liquid or a soft baking process is performed after applying the processing liquid to the wafer W. After each heating process, a cooling process is performed to cool the substrate W.

The baking chamber 510 may include a heating plate 511 and a cooling plate 512. The cooling plate 512 may be provided with a cooling unit, such as coolant or a thermoelectric element.

The cooling chamber 520 performs a cooling process to cool the substrate W prior to applying the processing liquid. The cooling chamber 520 may include a cooling plate. The cooling plate may include a cooling unit that may utilize various methods, such as cooling with coolant or cooling using a thermoelectric element, to cool the substrate W.

The interface module 600 connects the application and development module 400 to an exposure device 800. The interface module 600 includes an interface frame 610, a first interface buffer 620, a second interface buffer 630, and a transfer robot 640. The transfer robot 640 transfers the substrate transferred to the first and second interface buffers 620 and 630 after the application and development processes in the application and development module 400 have been completed to the exposure device 800. The first and second interface buffers 620 and 630 include a housing 621 and a support 622, and the transfer robot 640 and the application robot 421 may load/unload the substrate W to/from the support 622.

The related art substrate processing equipment described above with reference to FIGS. 1 to 3 is configured to be connected to the exposure device 800, so that the development module 402 performing a development process in conjunction with the exposure device 800 and the interface module 600 transferring the substrate to the exposure device 800 are essentially required.

Meanwhile, an application-dedicated substrate processing device (or (or coating-only substrate processing device) that does not perform an exposure process does not need to be configured to be connected to an exposure device and may be designed by omitting the related art development module and interface module.

The substrate processing device according to an embodiment of the present disclosure, described below, proposes a layout suitable for an application-dedicated substrate processing device.

Meanwhile, the substrate processing device 1000 according to an embodiment of the present disclosure, described below, may be described using the same terminology as the related art substrate processing equipment described above with reference to FIGS. 1 to 3 and the components using the same terminology may have the same basic structure and function, but a layout structure may be different.

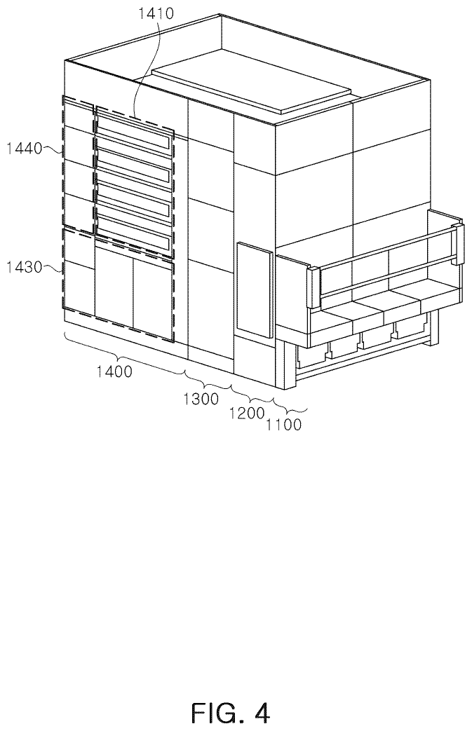

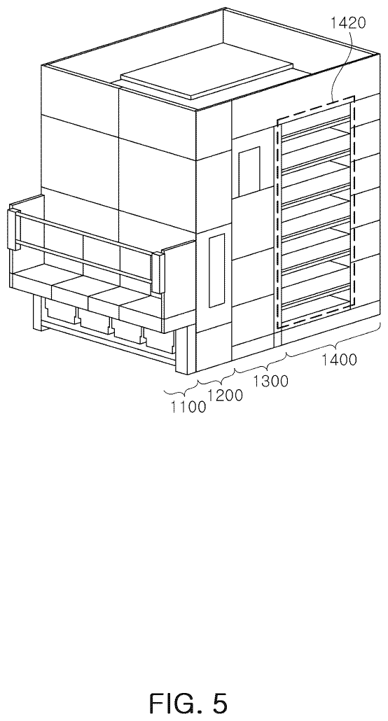

FIG. 4 is a perspective view including the front of a substrate processing device according to an embodiment of the present disclosure. FIG. 5 is a perspective view including the back of a substrate processing device according to an embodiment of the present disclosure.

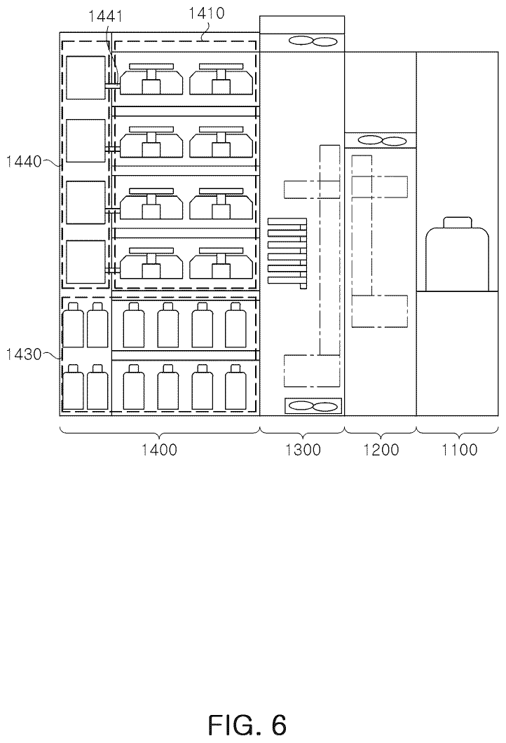

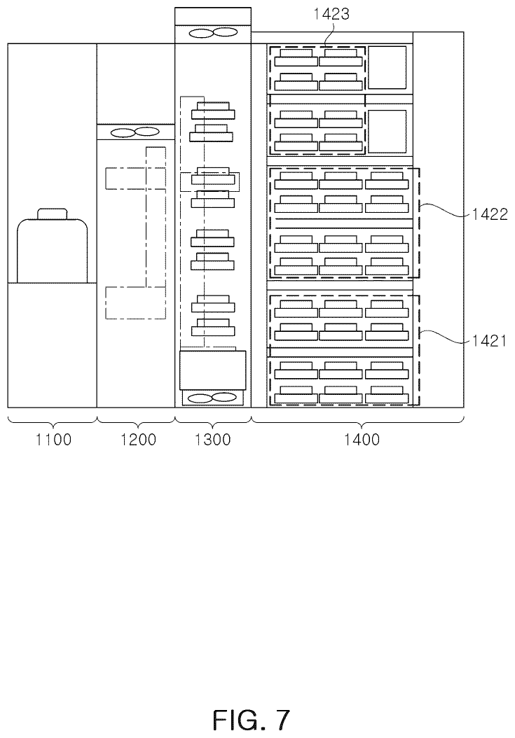

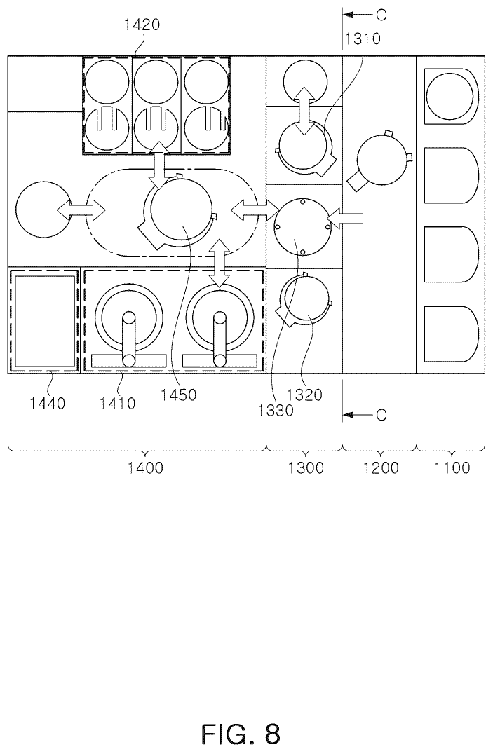

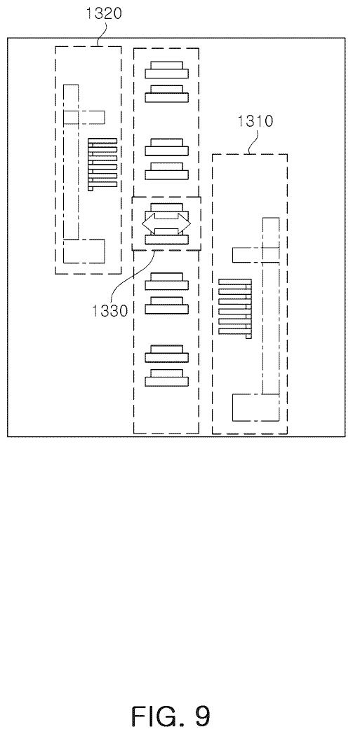

FIG. 6 is a front view of a substrate processing device according to an embodiment of the present disclosure. FIG. 7 illustrates a rear view of a substrate processing device according to an embodiment of the present disclosure. FIG. 8 illustrates a top view of a substrate processing device according to an embodiment of the present disclosure. FIG. 9 is a cross-sectional view of the substrate processing device of FIG. 8, taken in the C-C direction.

Referring to FIGS. 4 through 9, a substrate processing device according to an embodiment of the present disclosure may include a load port 1100, an index module 1200, a buffer module 1300, and an application module 1400.

The substrate processing device according to an embodiment of the present disclosure may not include an interface module and a development chamber, which are included in related art substrate processing equipment.

The load port 1100 and the index module 1200 according to an embodiment of the present disclosure may be the same as or similar to those of the related art substrate processing equipment described above, and thus, a detailed description thereof will be omitted.

The application module 1400 according to an embodiment of the present disclosure may include an application chamber portion 1410, a heat treatment chamber portion 1420, a PR bottle cabinet 1430, and a PR pump unit 1440.

The application module 1400 may include a plurality of layers. In an embodiment, the application module 1400 may be formed as a multi-stage structure with one to six layers. Furthermore, first and second layers of the application module 1400 may be defined as a lower layer, third and fourth layers as a middle layer, and fifth and sixth layers as an upper layer.

In the application module 1400, the application chamber portion 1410 and the PR bottle cabinet 1430 may be disposed on the front, and the heat treatment chamber portion 1420 may be disposed on the rear. Furthermore, the PR pump unit 1440 may be disposed on the front of the application module 1400 and on the side of the application chamber portion 1410.

The application chamber portion 1410 may include a lower film application chamber 1411 and a surface film application chamber 1412. The lower film application chamber 1411 may apply a lower film to the substrate, and the surface film application chamber 1412 may apply a surface film to the substrate.

The heat treatment chamber portion 1420 may include a preprocessing chamber 1421, a lower film heat treatment chamber 1422, and a surface film heat treatment chamber 1423. The preprocessing chamber 1421 may heat the substrate and remove organic substances before photoresist is applied to the substrate. The lower film heat treatment chamber 1422 may perform heat treatment after the lower film processing liquid is applied to the substrate. The surface film heat treatment chamber 1423 may perform heat treatment after the surface film processing liquid is applied to the substrate.

The PR bottle cabinet 1430 may be a storage space for storing a PR bottle accommodating PR used in the application chamber portion 1410. Since the application module 1400 according to an embodiment of the present disclosure does not include a development chamber, the PR may be stored in an empty space and may be rapidly supplied to the application chamber and easily stored.

The PR pump unit 1440 may supply PR from the PR bottle cabinet 1430 to the application chamber portion 1410. The PR pump unit 1440 may be disposed on the side of the application chamber portion 1410 and supply PR rapidly and efficiently. The PR pump unit 1440 may include a PR pipe 1441.

Since the PR pump unit 1440 is attached to the side of each layer of the application chamber portion 1410 with the same structure, the PR pipes 1441 disposed on each layer may all have the same length. As the PR pipe is longer, the time for PR to stagnate inside the pipe may become longer, and as the PR remains inside the pipe for a longer period of time, properties thereof may change, which may cause defects in the process. To prevent this, the PR pump unit 1440 may be disposed on the side of the application chamber to ensure a uniform supply of PR and facilitate control and management.

The buffer module 1300 according to an embodiment of the present disclosure The system may include a first robot 1310, a second robot 1320, and an exchange buffer 1330.

The first robot 1310 may load the substrate into the application module, and the second robot 1320 may remove the substrate from the application module.

In the case of the related art substrate processing equipment, the substrates are exchanged through the interface module. In contrast, in the substrate processing device according to an embodiment of the present disclosure, the interface module is eliminated, and the first robot 1310 and the second robot 1320 may exchange substrates through the exchange buffer 1330.

According to an embodiment of the present disclosure, the substrate processing device having a layout structure that may efficiently use application-dedicated equipment.

The effects of the present disclosure are not limited to the aforementioned effects, and those skilled in the art will appreciate that other effects, not mentioned above, may be derived from the components used in the specification and drawings below.

While embodiments have been illustrated and described above, it will be apparent to those skilled in the art that modifications and variations could be made without departing from the scope of the present disclosure as defined by the appended claims.

What is claimed is:

1. A substrate processing device comprising:
an application module applying a processing liquid to a substrate and performing heat treatment; and
a buffer module loading a substrate into the application module or removing a substrate from the application module,
wherein the application module includes:
an application chamber portion applying photoresist (PR) to the substrate;
a heat treatment chamber portion heat-treating the substrate; and
a PR bottle cabinet storing the PR.

2. The substrate processing device of claim 1, wherein the application module further includes a PR pump unit supplying the PR from the PR bottle cabinet to the application chamber portion.

3. The substrate processing device of claim 2, wherein the application module includes a plurality of layers including a lower layer, a middle layer, and an upper layer, and the PR bottle cabinet is provided in the lower layer of the application module.

4. The substrate processing device of claim 3, wherein the application chamber portion is provided in the middle layer or the upper layer of the application module.

5. The substrate processing device of claim 4, wherein the PR pump unit is provided in the middle layer or the upper layer of the application module and is arranged on a side of the application chamber portion.

6. The substrate processing device of claim 5, wherein the application module further includes a PR pipe supplying the PR by connecting the PR pump unit and the application chamber portion of each layer.

7. The substrate processing device of claim 6, wherein the PR pipe connected to each layer is configured to have the same length.

8. The substrate processing device of claim 1, wherein the heat treatment chamber portion includes a preprocessing chamber, a lower film heat treatment chamber, and a surface film heat treatment chamber.

9. The substrate processing device of claim 8, wherein the preprocessing chamber is provided in a lower layer of the application module, the lower film heat treatment chamber is provided in a middle layer of the application module, and the surface film heat treatment chamber is provided in a upper layer of the application module.

10. The substrate processing device of claim 9, wherein the application chamber portion includes a lower film application chamber and a surface film application chamber.

11. The substrate processing device of claim 10, wherein the lower film application chamber is provided in the middle layer of the application module, and the surface film application chamber is provided in the upper layer of the application module.

12. The substrate processing device of claim 1, wherein the buffer module includes a first robot locating the substrate into the application module and a second robot removing the substrate from the application module.

13. The substrate processing device of claim 12, wherein the buffer module further includes an exchange buffer through which the first robot and the second robot are able to exchange substrates with each other.

14. The substrate processing device of claim 1, wherein the substrate processing device is configured as an application-dedicated device.

15. A substrate processing device comprising:
an application module applying a processing liquid to a substrate and performing heat treatment; and
a buffer module loading a substrate into the application module or removing a substrate from the application module,
wherein the application module includes:
an application chamber portion applying photoresist (PR) to the substrate;
a heat treatment chamber portion heat-treating the substrate; and
a PR bottle cabinet storing the PR,
wherein the application chamber portion includes:
a support portion supporting and rotating the substrate;
a nozzle portion applying the PR to the substrate; and
a processing vessel recovering the PR applied to the substrate.

16. The substrate processing device of claim 15, wherein the application module further includes a PR pump unit supplying the PR from the PR bottle cabinet to the application chamber portion.

17. The substrate processing device of claim 16, wherein the application module includes a plurality of layers including a lower layer, a middle layer, and an upper layer, and the PR bottle cabinet is provided in the lower layer of the application module.

18. The substrate processing device of claim 17, wherein the application chamber portion is provided in the middle layer or upper layer of the application module, and the PR pump unit is provided in the middle layer or upper layer of the application module and is disposed on a side of the application chamber portion.

19. The substrate processing device of claim 18, wherein
the buffer module includes:
a first robot loading the substrate into the application module;
a second robot removing the substrate from the application module; and
an exchange buffer through which the first robot and the second robot are able to exchange substrates.

20. A substrate processing device comprising:
an application module applying a processing liquid to a substrate and performing heat treatment; and
a buffer module loading a substrate into the application module or removing the substrate from the application module,
wherein the application module includes:
an application chamber portion applying photoresist (PR) onto the substrate;
a heat treatment chamber portion heat-treating the substrate;
a PR bottle cabinet storing the PR;
a PR pump unit supplying the PR from the PR bottle cabinet to the application chamber portion; and
a PR pipe connecting the PR pump unit and the application chamber portion to supply the PR, and
wherein the application module includes a plurality of layers including a lower layer, a middle layer, and an upper layer, and
the heat treatment chamber portion includes a preprocessing chamber, a lower film heat treatment chamber, and a surface film heat treatment chamber,
the application chamber portion includes a lower film application chamber and a surface film application chamber,
the PR bottle cabinet and the preprocessing chamber are provided in the lower layer of the application module,
the PR pump unit, the lower film application chamber, and the lower film heat treatment chamber are provided in the middle layer of the application module,
the PR pump unit, the surface film application chamber, and the surface film heat treatment chamber are provided in the upper layer of the application module, and
the PR pipe connected to each layer is configured to have the same length.
